(19) United States
(12) Patent Application Publication
(10) Pub. No.: US 2025/0211217 A1
(43) Pub. Date: Jun. 26, 2025

(54) PHASE DIFFERENCE-BASED CALIBRATION USING MULTIPLE PHASE INTERPOLATORS

(71) Applicants: Mingming Xu, Phoenix, AZ (US); Xiaolang Zhang, San Jose, CA (US)

(72) Inventors: Mingming Xu, Phoenix, AZ (US); Xiaolang Zhang, San Jose, CA (US)

(21) Appl. No.: 18/395,062

(22) Filed: Dec. 22, 2023

(51) Int. Cl. H03K 5/1534

(52) U.S. Cl. CPC H03K 5/1534

(57) ABSTRACT

An apparatus includes a first phase detector circuit, a second phase detector circuit, a comparator circuit, and a calibration circuit. The first phase detector circuit is to generate a first reference voltage signal based on a first phase difference between a target phase signal and a first reference signal. The second phase detector circuit is configured to generate a second reference voltage signal based on a second phase difference between the target phase signal and a second reference signal. The comparator circuit is to generate a comparison voltage output based on the first reference voltage signal and the second reference voltage signal. The calibration circuit is to generate a plurality of control signals based on the comparison voltage output. At least one of the plurality of control signals includes a calibration code causing adjustment of a phase associated with the target phase signal.

### BACKGROUND

Time-interleaved analog-to-digital converters (ADCs) use multiple clock signals with fixed phase differences between them. However, the generation of clock signals with specific phase differences can be challenging due to process, voltage, temperature (PVT) variations and noise (e.g., power and ground noise as well as common mode noise).

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings in which:

FIG. 1 is a block diagram of a phase interpolator (PI)-based system for phase difference calibration, in accordance with some embodiments;

FIG. 2 is a graph showing phase traversal for 16 PI-generated phase signals referenced by corresponding PI indices, in accordance with some embodiments;

FIG. 3 is a block diagram of a PI-based one unit interval (1UI) phase difference calibration system using two reference signals, in accordance with some embodiments;

FIG. 4 is a block diagram of a phase detector used in the calibration system of FIG. 3, in accordance with some embodiments;

FIG. 5 is a graph of calibrating a phase signal with index PI8 selected from a plurality of 16 phase signals, in accordance with some embodiments;

FIG. 6 is a graph of calibrating phase signals with indices PI4 and PI12 selected from a plurality of 16 phase signals, in accordance with some embodiments;

FIG. 7 is a graph of calibrating phase signals with indices PI2, PI6, PI10, and PI14 selected from a plurality of 16 phase signals, in accordance with some embodiments;

FIG. 8 is a graph of calibrating phase signals with indices PI1, PI5, PI9, and PI13 selected from a plurality of 16 phase signals, in accordance with some embodiments;

FIG. 9 is a graph of calibrating phase signals with indices PI3, PI7, PI11, and PI15 selected from a plurality of 16 phase signals, in accordance with some embodiments;

FIG. 10 illustrates graphs of differential non-linearity (DNL) and integral non-linearity (INL) in relation to the PI index, in accordance with some embodiments;

FIG. 11 is a flow diagram of an example method for phase signal calibration, in accordance with some embodiments; and

FIG. 12 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for those of other embodiments. Embodiments outlined in the claims encompass all available equivalents of those claims.

As used herein, the term “chip” (or die) refers to a piece of a material, such as a semiconductor material, that includes a circuit, such as an integrated circuit or a part of an integrated circuit. The term “memory IP” indicates memory intellectual property. The terms “memory IP,” “memory device,” “memory chip,” and “memory” are interchangeable.

The term “processor” configured to carry out specific operations includes both a single processor configured to carry out all of the operations (e.g., operations or methods disclosed herein) as well as multiple processors individually configured to carry out some or all of the operations (which may overlap) such that the combination of processors carry out all of the operations.

In the time-interleaved ADC-based high-speed serial link receiver, multiple phase interpolators (PIs) are used to generate clocks with a fixed phase difference between adjacent phase signals, usually specified by using the unit interval (UI) of the data transmitted. In some aspects, the number of different phases used can be as high as 32 or even more. The accuracy of the phase difference is critical for the system's performance. Therefore, calibration to achieve an accurate phase difference is essential.

One step of the calibration is during the system power-up to compensate for the significant errors from the process, voltage change, and temperature change (PVT). For some specific applications, calibration time is a critical system specification to meet. The disclosed techniques include a fast and differential mode calibration to calibrate two adjacent PI phase differences (of two adjacent phase signals) to 1UI to reduce the phase difference error and shorten the calibration time.

The disclosed techniques include a calibration method on multiple clock phases that can be performed in a differential mode and is immune to the common mode noise or supply noise/variation. The disclosed techniques also avoid the use of a resistor DAC (RDAC) to generate any voltage reference signals and also avoid the use of firmware (FW). Compared to existing calibration techniques, the disclosed techniques avoid several calibration steps in the existing methods to save calibration time and improve accuracy and robustness.

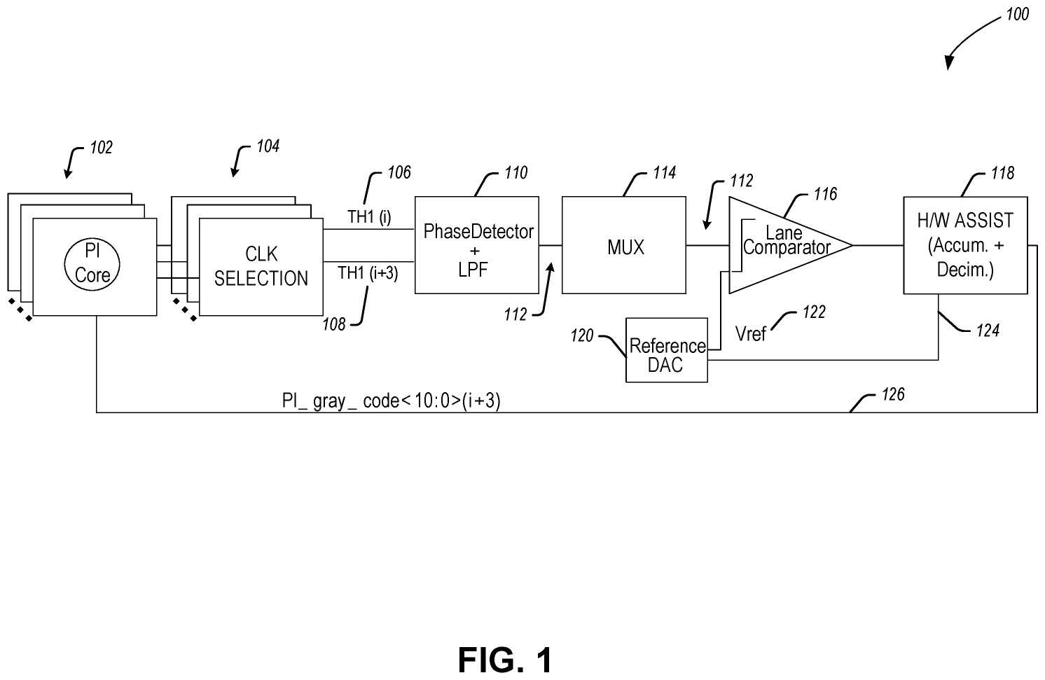

A single-ended method used to calibrate the phase difference for a total of 16 PIs (or 16 phase signals) is shown in FIG. 1. FIG. 1 is a block diagram of a phase interpolator (PI)-based system 100 for phase difference calibration, in accordance with some embodiments. Referring to FIG. 1, system 100 includes PI cores 102, clock selection circuits 104, a phase detector 110, a multiplexer 114, a comparator 116, a hardware assist circuit 118 (which can be configured to function in firmware), and a reference DAC 120.

The PI cores 102 generate a plurality of phase signals (e.g., clock signals with different phases, which can be 16 separate phase signals) received by the clock selection circuits 104. The clock selection circuits 104 select phase signals 106 and 108. As used herein, the term PI indicates a phase interpolator as well as a phase signal generated by the phase interpolator. In this regard, phase signals 106 and 108 are also referred to as PIs 106 and 108.

Two PIs (e.g., PIs 106 and 108), nominally with 3UI phase difference, are communicated to the calibration loop for calibration using the phase detector 110, the multiplexer 114, the comparator 116, the hardware assist circuit 118, and the reference DAC 120.

Example processing functions for the reference voltage 122 calibration are as follows. Corresponding auxiliary circuits are enabled for calibration (e.g., the phase detector 110, the multiplexer 114, the comparator 116, the hardware assist circuit 118, and the reference DAC 120). phase signals 106 and 108 (e.g., PI<i> and PI<i+3> (i=0, 1, . . . , 15)) are selected and communicated to the phase detector 110 (which can include a low pass filter (LPF)) to generate a DC voltage level 112, which represents the phase difference between the PI<i> and PI<i+3> (e.g., phase signals 106 and 108). The comparator 116 takes two inputs—the first input is the DC voltage level 112 received from the phase detector 110 via the multiplexer 114, and the other input is the reference voltage 122 (or Vref) from the reference DAC 120 and makes comparisons. Based on the comparator output, the firmware engine (e.g., the hardware assist circuit 118) adjusts the control code to the reference DAC 120 via control signal 124 to adjust Vref. It stops until Vref is equal to the DC voltage level 112 from the other input of the comparator 116. The firmware then records the final control code to the reference DAC 120.

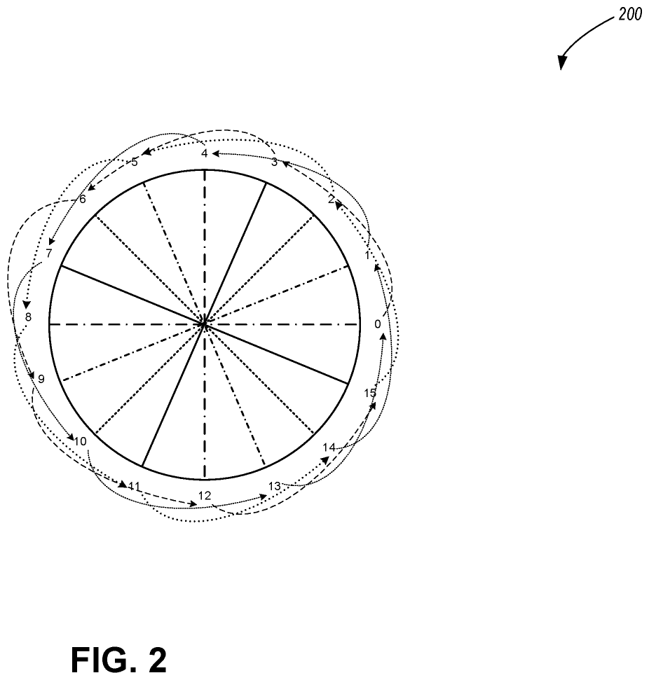

The above processing can be repeated until all the 16 PI phases are traversed. The traversals of the phases for all 16 PIs (or phase signals) are illustrated in FIG. 2. FIG. 2 is graph 200 showing phase traversal for 16 PI-generated phase signals referenced by corresponding PI indices, in accordance with some embodiments.

In some aspects, the 16 recorded codes generated during the traversal of FIG. 2 can be averaged and used to control the reference DAC 120 to generate Vref, which is used as the reference voltage for the following PI phase calibration.

Example processing functions for the 1UI phase difference calibration are as follows. The clock selection circuits 104 select phase signals 106 and 108 (PI<i> and PI<i+3> (i=0, 1, . . . , 15)) and communicate such signals to the phase detector 110. The phase detector 110 generates DC voltage level 112, which represents the phase difference between PI<i> and PI<i+3>. The DC voltage level 112 is sent to the comparator 116.

The firmware (e.g., the hardware assist circuit 118) adjusts the PI control code to the PI<i+3> (e.g., via control signal 126), while the control code to the PI<i> is held unchanged until the DC voltage level 112 to the comparator equals to Vref. The firmware records the PI control code to PI<i+3>, which control code represents the PI<i+3> phase that is 3UI apart from the phase in PI<i>. In some aspects, the above steps are repeated until all the PI phases are traversed to complete the calibration. After the calibration is completed, the firmware records the control codes (e.g., communicated via control signal 126) used to represent the PI phases. The corresponding auxiliary circuits (e.g., the phase detector 110, the multiplexer 114, the comparator 116, the hardware assist circuit 118, and the reference DAC 120) can be disabled to save power.

The following are some drawbacks associated with the calibration processing discussed in connection with FIG. 1 and FIG. 2:
(a) The calibration involves the use of firmware, which is slow.
(b) The first step in the calibration method of FIG. 1 is to calibrate the reference voltage Vref, which is slow and can take half of the total calibration time spent.
(c) The calibrated Vref is generated directly from the power supply, which can vary due to the supply variation or noise from the power supply.
(d) The calibration system works in a single-ended mode, which is susceptible to noise.
(e) The search of the control code to the reference DAC and the PI is a linear search, with large numbers of PI and higher accuracy requirements for the reference DAC and PI phase difference. Consequently, the search process is slow (e.g., in the millisecond range for a 4 GHz clock, 16 PI).

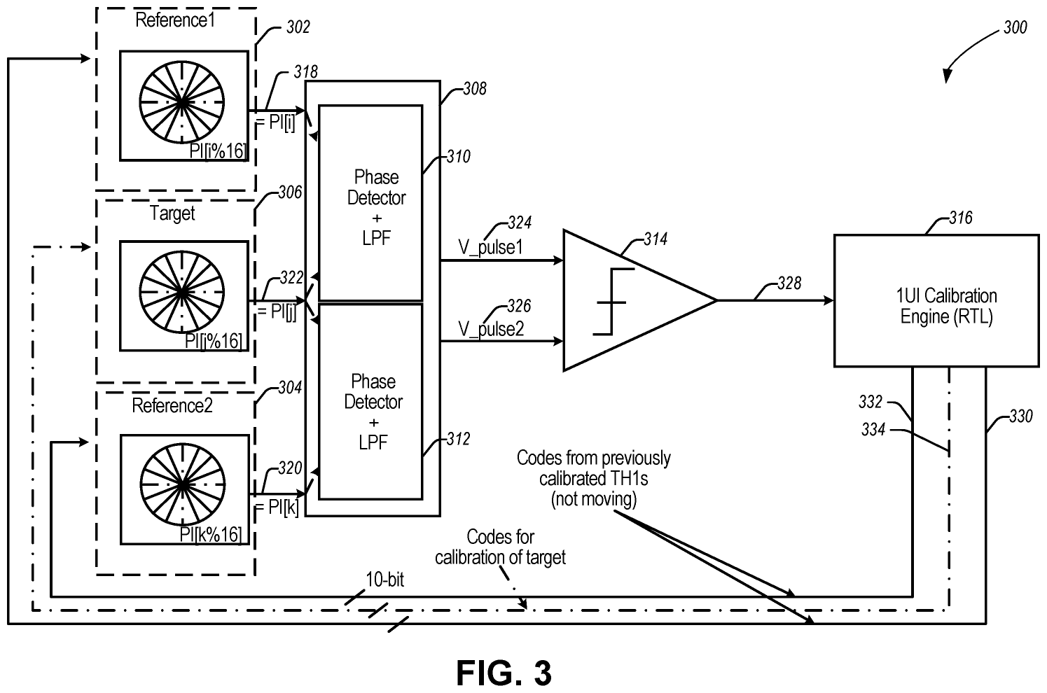

In some aspects, the disclosed techniques can be used to configure a PI-based one-unit interval (1UI) phase difference calibration system with two references (e.g., as illustrated in FIG. 3).

FIG. 3 is a block diagram of a PI-based 1UI phase difference calibration system 300 using two reference signals, in accordance with some embodiments. Referring to FIG. 3, system 300 includes PI 302, PI 304, PI 306, an integrated phase detector (PD) 308 (including PD circuits 310 and 312), a comparator circuit 314, and a calibration circuit 316.

In operation, reference phase signal 318 and target phase signal 322 are used by PD circuit 310 to generate a first reference voltage signal (e.g., DC voltage level 324). Similarly, reference phase signal 320 and target phase signal 322 are used by PD circuit 312 to generate a second reference voltage signal (e.g., DC voltage level 326). DC voltage levels 324 and 326 are processed by comparator circuit 314 to generate a comparison voltage output 328. The calibration circuit 316 is to generate a plurality of control signals (e.g., control signals 330-334) based on the comparison voltage output 328. At least one of the plurality of control signals (e.g., control signal 334) includes a calibration code causing adjustment of a phase associated with the target phase signal 322.

PD circuits 310 and 312 are configured to detect a wide phase difference as part of a differential-based calibration operation and generate the differential inputs to the comparator circuit 314. For each target PI phase (e.g., target phase signal 322), two reference phases can be used (e.g., reference phase signals 318 and 320) for calibration of the target phase signal. The reference phase signals can be selected from already (e.g., previously) calibrated PI phases (or phase signals). The control code to the target PI (e.g., PI 306) can be moved (adjusted) so the rising edge of the target PI output is centered at the two rising edges of the two reference phases of the corresponding reference phase signals 318 and 320.

In some aspects, the calibration circuit 316 is a 1UI calibration engine implemented in RTL, which can include coarse and fine search steps. In the coarse search steps, a binary search or other (variable) large code steps can be used to save on the calibration time.

In an aspect based on 16 phase signals (or 16 PIs), for the initial calibration, one out of the 16 PIs is selected as the reference and starting point for the calibration. For example, a phase signal (or PI) with index 0 (e.g., PI0) is selected for this purpose. PI8 is then calibrated with reference to PI0 by centering the rising edge of PI8 to the two consecutive rising edges of PI0. PI4 and PI12 then use PI0 and PI8 as the references, and the edges are centered on the rising edge of PI8 and PI0. The above sequence can be repeated until all of the PIs (e.g., all 16 PIs) are traversed. Table 1 below shows one such calibration sequence that can be used with system 300 of FIG. 3.

TABLE 1

| | | PI to be | |
|---|---|---|---|
| Calibration | Reference PI | calibrated | Reference PI |
| sequence | (reference1) | (Target) | (reference2) |
| 15 | PI10 | PI15 | PI4 |
| 7 | PI8 | PI14 | PI4 |
| 14 | PI8 | PI13 | PI2 |
| 3 | PI8 | PI12 | PI0 |
| 13 | PI6 | PI11 | PI0 |
| 6 | PI4 | PI10 | PI0 |
| 12 | PI4 | PI9 | PI14 |
| 1 | PI0 | PI8 | PI0 |
| 11 | PI2 | PI7 | PI12 |
| 5 | PI0 | PI6 | PI12 |
| 10 | PI0 | PI5 | PI10 |
| 2 | PI0 | PI4 | PI8 |
| 9 | PI14 | PI3 | PI8 |
| 4 | PI12 | PI2 | PI8 |
| 8 | PI12 | PI1 | PI6 |
| 0 | — | PI0 | — |

In some aspects, PI 302 is coupled to PD circuit 310 and selects the first reference signal (e.g., reference phase signal 318) from a plurality of phase signals based on a first control signal (e.g., control signal 330) of the plurality of control signals. PI 304 is coupled to PD circuit 312 and selects the second reference signal (e.g., reference phase signal 320) from a plurality of phase signals based on a second control signal (e.g., control signal 332) of the plurality of control signals. PI 306 is coupled to PD circuit 312 and PD circuit 310. PI 306 is the target reference phase (e.g., target phase signal 322) and is selected from the plurality of phase signals based on the first control signal and the second control signal.

In some aspects, the calibration circuit 316 adjusts a rising edge of the target reference signal based on a calibration code (e.g., control signal 334). The adjustment causes the rising edge of the target reference signal to be between a rising edge of the first reference signal and a rising edge of the second reference signal.

The differential mode operation associated with the calibration performed by system 300 does not use a reference DAC and a Vref-based calibration, which results in reduced calibration time and immunity to the common mode noise. In some aspects, the calibration performed by system 300 can be repeated for the second round if the phase accuracy requirement is higher. In this repeated calibration, since the calibration code is already approaching the final target, the code search range can be much smaller and add only a small amount of calibration time.

In some aspects, the search steps for each PI phase calibration can be nonlinear and can be divided into coarse search and fine search steps, which can greatly reduce the calibration time (in the 200 us range for a 4 GHz clock for 16 PI). Additionally, the calibration circuit 316 can be implemented using RTL instead of firmware, which also saves calibration time. In some aspects, the disclosed 1UI phase difference calibration method can be applied to cases where fixed phase differences are required in multi-phase clocks.

In aspects when calibration time is a critical specification, the number of the PD circuits and comparator circuits in system 300 can be increased so the calibrations on different PIs can be run in parallel.

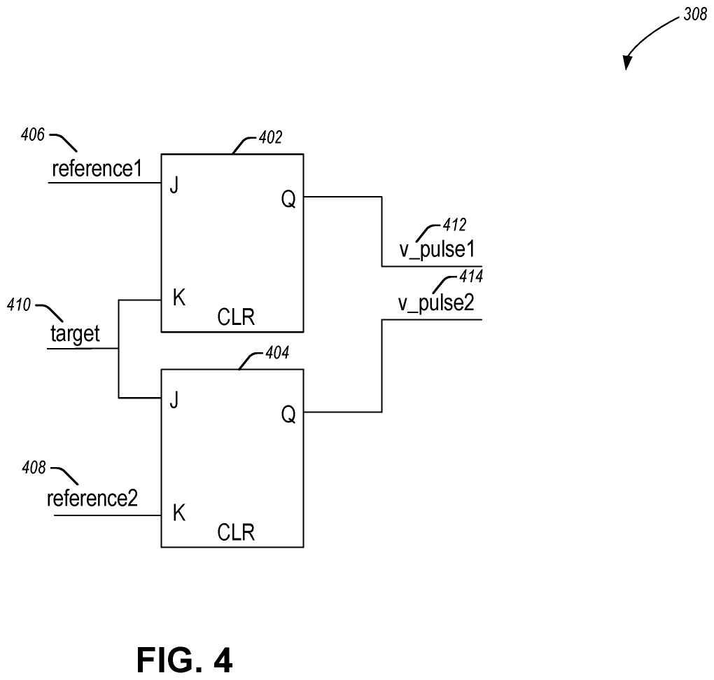

FIG. 4 is a block diagram of the integrated PD 308 used in the calibration system of FIG. 3, in accordance with some embodiments.

The integrated PD 308 can be configured to detect the arrival sequence of the rising edge and differentiate the phase difference that is larger than 180 degrees. The integrated PD 308 can be configured as symmetrical to reduce mismatch. In this regard, the integrated PD 308 can be based on the use of JK flip-flops.

Referring to FIG. 4, in some aspects, integrated PD 308 includes a first flip-flop circuit 402 (e.g., configured as PD circuit 310) and a second flip-flop circuit 404 (e.g., configured as PD circuit 312).

In some aspects, the J terminal of the first flip-flop circuit 402 receives reference phase signal 406 (e.g., the reference phase signal 318), and the K terminal receives a target phase signal 410 (e.g., target phase signal 322) to generate reference voltage signal 412 (e.g., DC voltage level 324). The J terminal of the second flip-flop circuit 404 receives reference phase signal 408 (e.g., the reference phase signal 320), and the K terminal receives the target phase signal 410 to generate reference voltage signal 414 (e.g., DC voltage level 326).

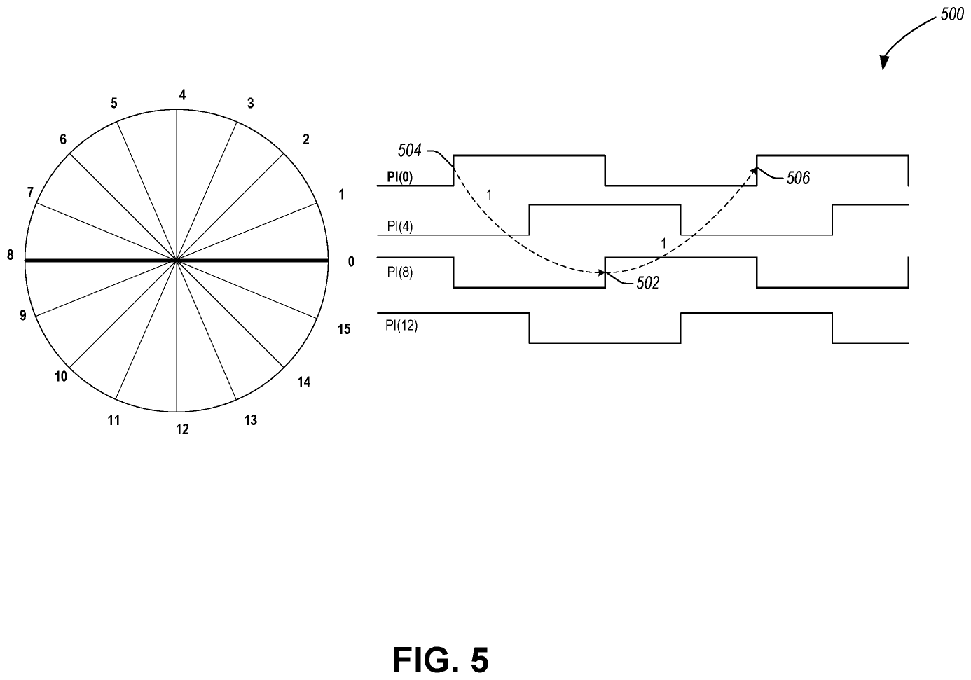

A more detailed description of the calibration performed by system 300 in connection with 16 phase signals (16 PI) is discussed in connection with FIG. 5-FIG. 9.

FIG. 5 is graph 500 of calibrating a phase signal with index PI8 selected from a plurality of 16 phase signals, in accordance with some embodiments.

In reference to system 300, the corresponding auxiliary circuits are enabled (activated) for calibration (e.g., MUX, buffers, phase detectors, comparators, etc.).

As an initial step, PI8 is calibrated. The target is to center the rising edge 502 of PI8 to the two consecutive rising edges 504 and 506 in PI0. The centering procedures are as follows.

PI0 is used only as the reference phase signal. Signal pairs (PI0, PI8) and (PI8, PI0) are sent to the two PDs 310 and 312. The extracted DC level voltages are the inputs to the comparator circuit 314. Then, the control code (e.g., control signal 334) to PI8 is updated based on the comparator circuit output. This calibration procedure continues until the comparator circuit output starts to toggle between 0 and 1 for a certain time.

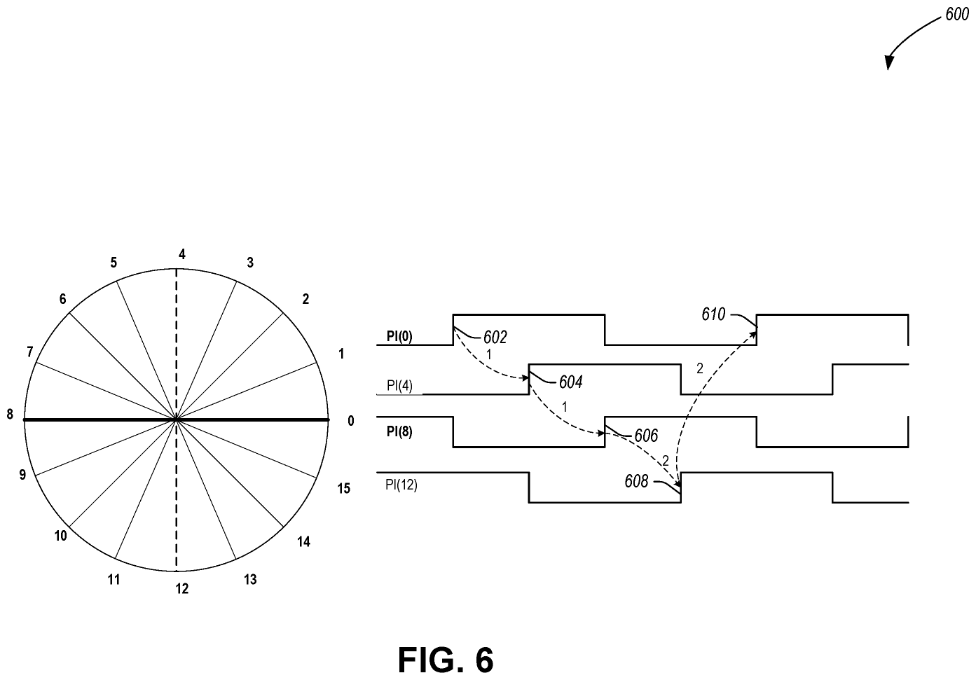

FIG. 6 is graph 600 of calibrating phase signals with indices PI4 and PI12 selected from a plurality of 16 phase signals, in accordance with some embodiments. Referring to FIG. 6, the calibration circuit 316 uses PI0 and already calibrated PI8 as the reference phase signals. The calibration circuit 316 centers the PI4 rising edge 604 with regard to the rising edges 602 and 606 of PI0 and PI8, respectively. The calibration circuit 316 centers the PI12 rising edge 608 with regard to the rising edges 606 and 610 of PI8 and PI0, respectively (the edge centering steps are the same as those in FIG. 5).

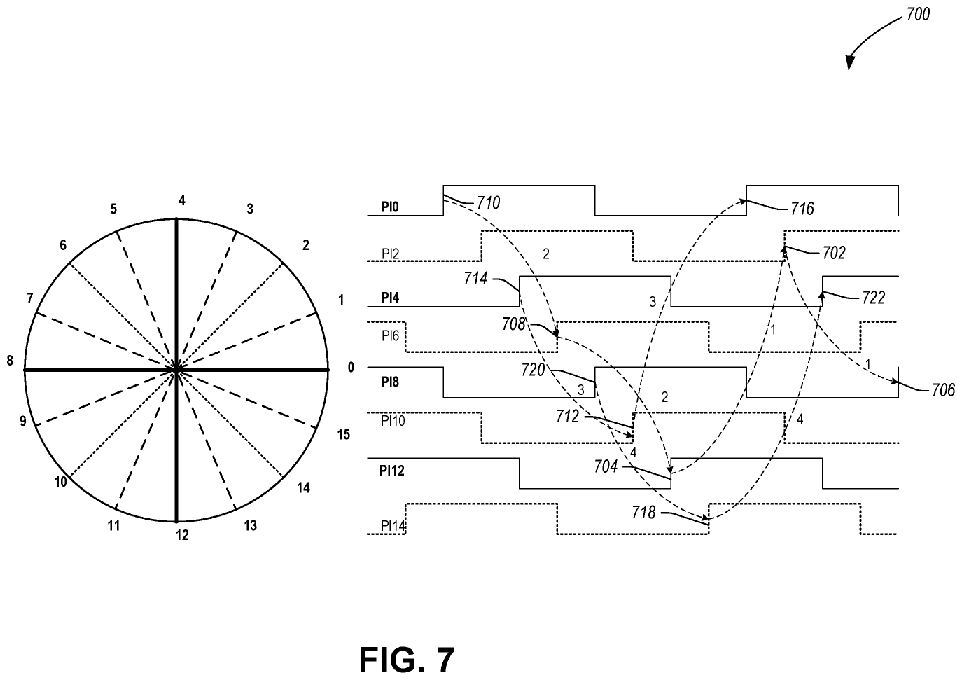

FIG. 7 is graph 700 of calibrating phase signals with indices PI2, PI6, PI10, and PI14 selected from a plurality of 16 phase signals, in accordance with some embodiments. Referring to FIG. 7, the calibration circuit 316 uses PI0, PI8, PI4, and PI12 as the reference phase signals. The calibration circuit 316 centers the PI2 rising edge 702 with regard to the rising edges 704 and 706 of PI12 and PI8, respectively. The calibration circuit 316 centers the PI6 rising edge 708 with regard to the rising edges 710 and 704 of PI0 and PI12, respectively. The calibration circuit 316 centers the PI10 rising edge 712 with regard to the rising edges 714 and 716 of PI4 and PI0, respectively. The calibration circuit 316 centers the PI14 rising edge 718 with regard to the rising edges 720 and 722 of PI8 and PI4, respectively (the edge-centering steps are the same as those in FIG. 5).

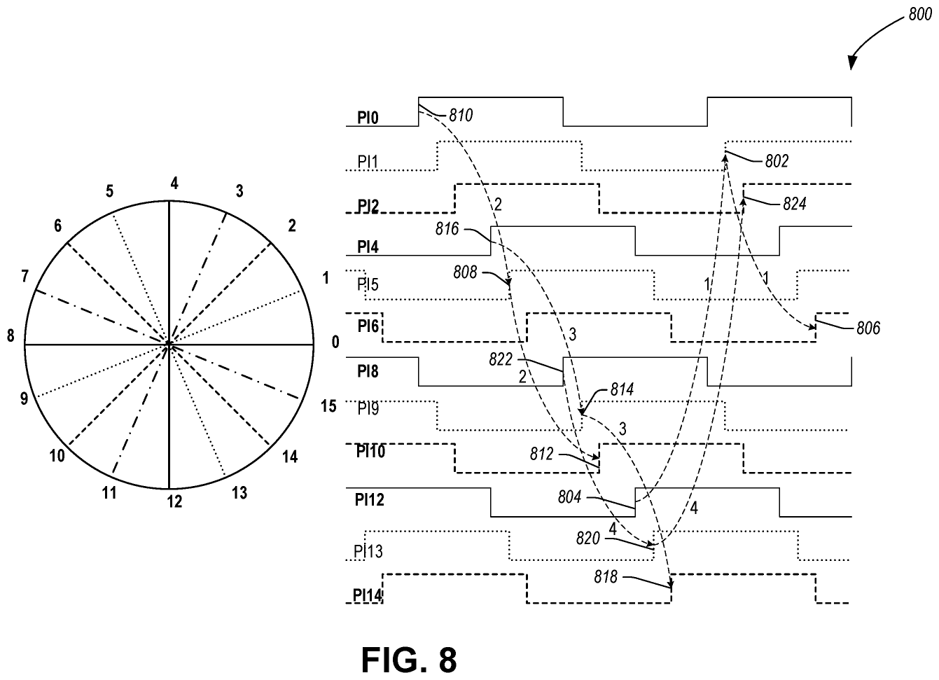

FIG. 8 is graph 800 of calibrating phase signals with indices PI1, PI5, PI9, and PI13 selected from a plurality of 16 phase signals, in accordance with some embodiments. Referring to FIG. 8, the calibration circuit 316 uses PI0, PI10, PI12, PI6, PI8, PI2, PI4, and PI14 as the reference phase signals. The calibration circuit 316 centers the PI1 rising edge 802 with regard to the rising edges 804 and 806 of PI12 and PI6, respectively. The calibration circuit 316 centers the PI5 rising edge 808 with regard to the rising edges 810 and 812 of PI0 and PI10, respectively. The calibration circuit 316 centers the PI9 rising edge 814 with regard to the rising edges 816 and 818 of PI4 and PI14, respectively. The calibration circuit 316 centers the PI13 rising edge 820 with regard to the rising edges 822 and 824 of PI8 and PI2, respectively (the edge-centering steps are the same as those in FIG. 5).

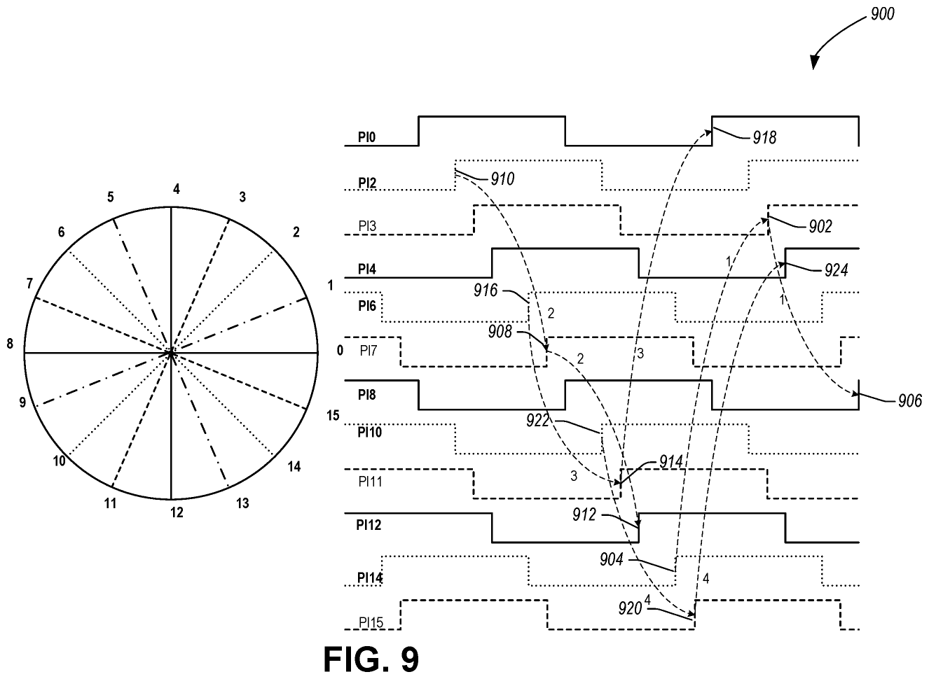

FIG. 9 is graph 900 of calibrating phase signals with indices PI3, PI7, PI11, and PI15 selected from a plurality of 16 phase signals, in accordance with some embodiments;

Referring to FIG. 8, the calibration circuit 316 uses PI0, PI10, PI12, PI6, PI8, PI2, PI4, and PI14 as the reference phase signals. The calibration circuit 316 centers the PI3 rising edge 902 with regard to the rising edges 904 and 906 of PI14 and PI8, respectively. The calibration circuit 316 centers the PI7 rising edge 908 with regard to the rising edges 910 and 912 of PI2 and PI12, respectively. The calibration circuit 316 centers the PI11 rising edge 914 with regard to the rising edges 916 and 918 of PI6 and PI0, respectively. The calibration circuit 316 centers the PI15 rising edge 920 with regard to the rising edges 922 and 924 of PI10 and PI14, respectively (the edge-centering steps are the same as those in FIG. 5).

In some aspects, the calibrations for the PI within each step from FIG. 5 to FIG. 9 can be run in parallel. The processing in FIG. 8 and FIG. 9 can also be configured to run in parallel to reduce the calibration time further.

In some aspects, a Verilog-A-based calibration engine is implemented, and all the other blocks are implemented in a Finfet process to demonstrate the calibration validity. In this simulation, there are 16 PI, each having a 10-bit control code, the clock runs at 4 GHZ, and the ideal 1UI phase difference is 15.625 ps.

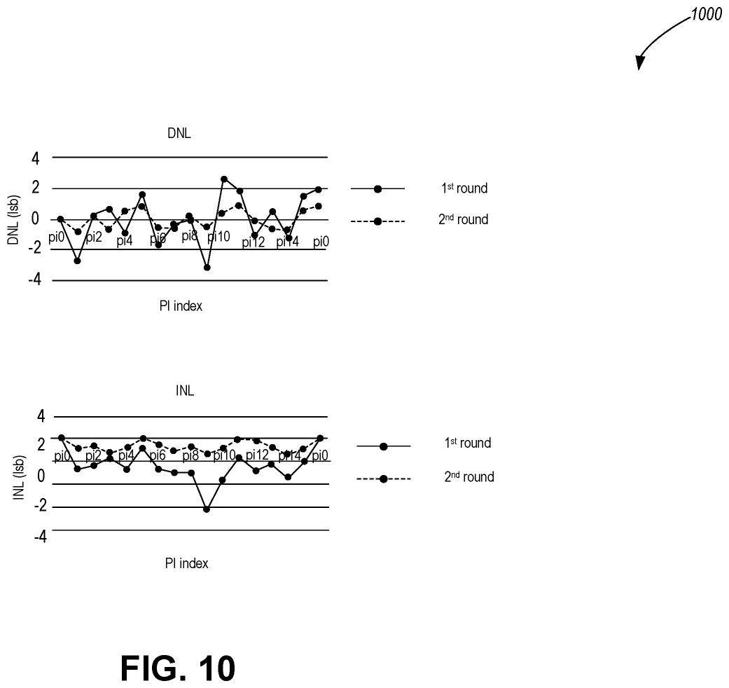

To further improve the calibration accuracy, a 2nd round of calibration can be run, with the initial control code from the 1st round of calibration and a narrower search range. FIG. 10 illustrates graphs 1000 of differential non-linearity (DNL) and integral non-linearity (INL) in relation to the PI index from the above two rounds of calibration, in accordance with some embodiments;

FIG. 10 illustrates the improved accuracy from the 2nd round at the cost of more calibration time that is required. Since the 2nd round calibration will adjust the control code within a small range, the search can be done in a much shorter time compared to the 1st round calibration.

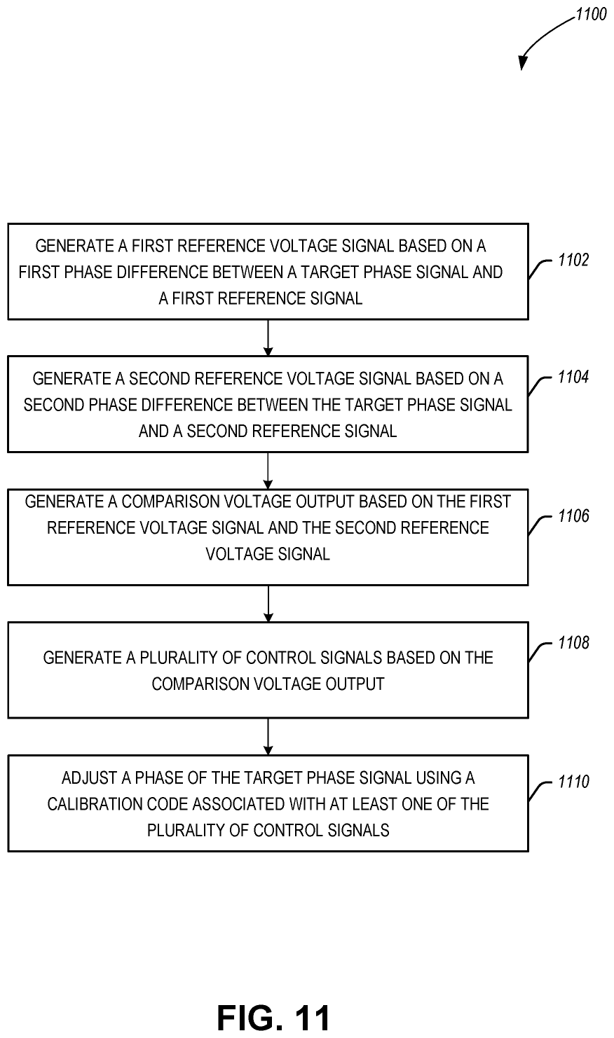

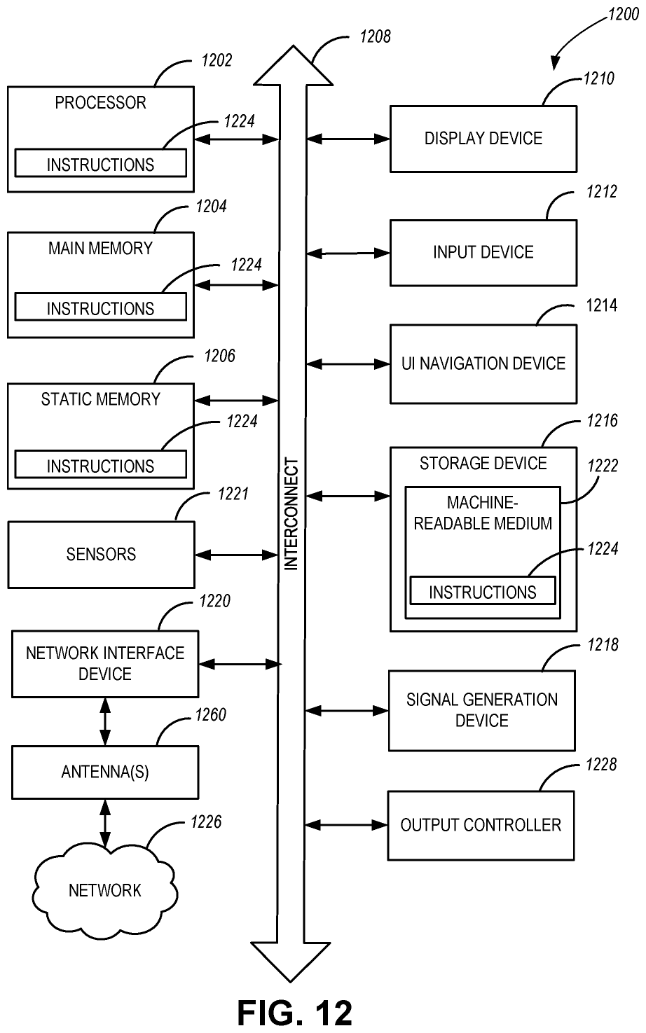

FIG. 11 is a flow diagram of an example method 1100 for phase signal calibration, in accordance with some embodiments. Referring to FIG. 11, method 1100 includes operations 1102, 1104, 1106, 1108, and 1110, which may be executed by an embedded controller or another processor of a computing device (e.g., hardware processor 1202 of machine 1200 illustrated in FIG. 12, which can include one or more of the circuits discussed in connection with FIGS. 1-10). In some embodiments, one or more of the circuits discussed in connection with FIGS. 1-10 can perform the functionalities listed in FIG. 11 as well as in the examples listed below.

At operation 1102, a first reference voltage signal (e.g., DC voltage level 324) is generated based on a first phase difference between a target phase signal (e.g., target phase signal 322) and a first reference signal (e.g., reference phase signal 318).

At operation 1104, a second reference voltage signal (e.g., DC voltage level 326) is generated based on a second phase difference between the target phase signal (e.g., target phase signal 322) and a second reference signal (e.g., reference phase signal 320).

At operation 1106, a comparison voltage output 328 is generated based on the first reference voltage signal and the second reference voltage signal.

At operation 1108, a plurality of control signals (e.g., control signals 330-334) is generated based on the comparison voltage output.

At operation 1110, a phase of the target phase signal is adjusted using a calibration code associated with at least one of the plurality of control signals (e.g., control signal 334).

FIG. 12 illustrates a block diagram of an example machine 1200 upon which any one or more of the techniques (e.g., methodologies) discussed herein may perform. In alternative embodiments, the machine 1200 may operate as a standalone device or may be connected (e.g., networked) to other machines. In a networked deployment, machine 1200 may operate in the capacity of a server machine, a client machine, or both in server-client network environments. In an example, machine 1200 may function as a peer machine in a peer-to-peer (P2P) (or other distributed) network environment. The machine 1200 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 1200 may include a hardware processor 1202 (e.g., a central processing unit (CPU), a graphics processing unit (GPU), a hardware processor core, or any combination thereof), a main memory 1204, and a static memory 1206, some or all of which may communicate with each other via an interlink (e.g., bus) 1208. In some aspects, the main memory 1204, the static memory 1206, or any other type of memory (including cache memory) used by machine 1200 can be configured based on the disclosed techniques or can implement the disclosed memory devices.

Specific examples of main memory 1204 include Random Access Memory (RAM) and semiconductor memory devices, which may include, in some embodiments, storage locations in semiconductors such as registers. Specific examples of static memory 1206 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 1200 may further include a display device 1210, an input device 1212 (e.g., a keyboard), and a user interface (UI) navigation device 1214 (e.g., a mouse). In an example, the display device 1210, the input device 1212, and the UI navigation device 1214 may be a touchscreen display. The machine 1200 may additionally include a storage device (e.g., drive unit or another mass storage device) 1216, a signal generation device 1218 (e.g., a speaker), a network interface device 1220, and one or more sensors 1221, such as a global positioning system (GPS) sensor, compass, accelerometer, or other sensors. The machine 1200 may include an output controller 1228, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 1202 and/or instructions 1224 may comprise processing circuitry and/or transceiver circuitry.

The storage device 1216 may include a machine-readable medium 1222 on which one or more sets of data structures or instructions 1224 (e.g., software) embodying or utilized by any one or more of the techniques or functions described herein can be stored. Instructions 1224 may also reside, completely or at least partially, within the main memory 1204, within static memory 1206, or the hardware processor 1202 during execution thereof by the machine 1200. In an example, one or any combination of the hardware processor 1202, the main memory 1204, the static memory 1206, or the storage device 1216 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 1222 is illustrated as a single medium, the term “machine-readable medium” may include a single medium or multiple media (e.g., a centralized or distributed database and/or associated caches and servers) configured to store instructions 1224.

An apparatus of the machine 1200 may be one or more of a hardware processor 1202 (e.g., a central processing unit (CPU), a graphics processing unit (GPU), a hardware processor core, or any combination thereof), a main memory 1204 and a static memory 1206, one or more sensors 1221, a network interface device 1220, one or more antennas 1260, a display device 1210, an input device 1212, a UI navigation device 1214, a storage device 1216, instructions 1224, a signal generation device 1218, and an output controller 1228. The apparatus may be configured to perform one or more of the methods and/or operations disclosed herein. The apparatus may be intended as a component of machine 1200 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 1200 and that causes machine 1200 to perform any one or more of the techniques of the present disclosure, or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 1224 may further be transmitted or received over a communications network 1226 using a transmission medium via the network interface device 1220 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, a Universal Mobile Telecommunications System (UMTS) family of standards, peer-to-peer (P2P) networks, a cellular network such as 3GPP Fifth Generation (5G) (and beyond) wireless network, among others.

In an example, the network interface device 1220 may include one or more physical jacks (e.g., Ethernet, coaxial, or phone jacks) or one or more antennas to connect to the communications network 1226. In an example, the network interface device 1220 may include one or more antennas 1260 to wirelessly communicate using at least one single-input multiple-output (SIMO), multiple-input multiple-output (MIMO), or multiple-input single-output (MISO) techniques. In some examples, the network interface device 1220 may wirelessly communicate using multiple-user MIMO techniques. The term “transmission medium” shall be taken to include any intangible medium that can store, encode, or carry instructions for execution by the machine 1200 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc., are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of a system on chip, a set of intercommunicating functional blocks, or similar, although the scope of the disclosure is not limited in this respect.

Described implementations of the subject matter can include one or more features, alone or in combination, as illustrated below by way of examples.

Example 1 is an apparatus comprising a first flip-flop circuit including a first input terminal and a second input terminal; a second flip-flop circuit including a first input terminal and a second input terminal; the second input terminal of the first flip-flop circuit coupled to the first input terminal of the second flip-flop circuit; a first phase interpolator (PI) circuit including an output terminal coupled to the first input terminal of the first flip-flop circuit; and a second PI circuit including an output terminal coupled to the second input terminal of the second flip-flop circuit.

In Example 2, the subject matter of Example 1 includes a third PI circuit, including an output terminal coupled to the second input terminal of the first flip-flop circuit and the first input terminal of the second flip-flop circuit.

In Example 3, the subject matter of Example 2 includes a comparator circuit, including a first input terminal coupled to an output terminal of the first flip-flop circuit and a second input terminal coupled to an output terminal of the second flip-flop circuit.

In Example 4, the subject matter of Example 3 includes a calibration circuit, including an input terminal coupled to an output terminal of the comparator circuit.

In Example 5, the subject matter of Example 4 includes subject matter where a first output terminal of the calibration circuit is coupled to the first PI circuit.

In Example 6, the subject matter of Example 5 includes subject matter where a second output terminal of the calibration circuit is coupled to the second PI circuit.

In Example 7, the subject matter of Example 6 includes subject matter where a third output terminal of the calibration circuit is coupled to the third PI circuit.

In Example 8, the subject matter of Examples 1-7 includes one or more interconnects coupled to the first flip-flop circuit, the second flip-flop circuit, the first PI circuit, the second PI circuit, the third PI circuit, the comparator circuit, and the calibration circuit.

Example 9 is an apparatus comprising: a first phase detector circuit configured to generate a first reference voltage signal based on a first phase difference between a target phase signal and a first reference signal; a second phase detector circuit configured to generate a second reference voltage signal based on a second phase difference between the target phase signal and a second reference signal; a comparator circuit configured to generate a comparison voltage output based on the first reference voltage signal and the second reference voltage signal; and a calibration circuit configured to generate a plurality of control signals based on the comparison voltage output, at least one of the plurality of control signals comprising a calibration code causing adjustment of a phase associated with the target phase signal.

In Example 10, the subject matter of Example 9 includes a first phase interpolator (PI) circuit coupled to the first phase detector circuit, the first PI circuit to select the first reference signal from a plurality of phase signals based on a first control signal of the plurality of control signals.

In Example 11, the subject matter of Example 10 includes a second PI circuit coupled to the second phase detector circuit, the second PI circuit to select the second reference signal from the plurality of phase signals based on a second control signal of the plurality of control signals.

In Example 12, the subject matter of Example 11 includes a third PI circuit coupled to the first phase detector circuit and the second phase detector circuit, the third PI circuit to select the target reference signal from the plurality of phase signals based on the first control signal and the second control signal.

In Example 13, the subject matter of Example 12 includes subject matter where to perform the adjustment of the phase, the third PI circuit is to adjust a rising edge of the target reference signal based on the calibration code, the adjustment causing the rising edge of the target reference signal to be between a rising edge of the first reference signal and a rising edge of the second reference signal.

In Example 14, the subject matter of Examples 12-13 includes subject matter where the first PI circuit is to select the first reference signal from a subset of the plurality of phase signals, the subset comprising previously calibrated phase signals.

In Example 15, the subject matter of Example 14 includes subject matter where the second PI circuit is to select the second reference signal from the subset of the plurality of phase signals.

In Example 16, the subject matter of Examples 9-15 includes subject matter where the apparatus comprises a processor, and wherein the processor includes one or more of the first phase detector circuit, the second phase detector circuit, the first PI circuit, the second PI circuit, the third PI circuit, the comparator circuit, and the calibration circuit.

In Example 17, the subject matter of Examples 9-16 includes one or more interconnects coupling two or more of the first phase detector circuit, the second phase detector circuit, the first PI circuit, the second PI circuit, the third PI circuit, the comparator circuit, and the calibration circuit.

Example 18 is a method comprising generating a first reference voltage signal based on a first phase difference between a target phase signal and a first reference signal; generating a second reference voltage signal based on a second phase difference between the target phase signal and a second reference signal; generating a comparison voltage output based on the first reference voltage signal and the second reference voltage signal; generating a plurality of control signals based on the comparison voltage output; and adjusting a phase of the target phase signal using a calibration code associated with at least one of the plurality of control signals.

In Example 19, the subject matter of Example 18 includes selecting the first reference signal from a plurality of phase signals based on a first control signal of the plurality of control signals.

In Example 20, the subject matter of Example 19 includes selecting the second reference signal from the plurality of phase signals based on a second control signal of the plurality of control signals.

In Example 21, the subject matter of Example 20 includes selecting the target reference signal from the plurality of phase signals based on the first control signal and the second control signal.

In Example 22, the subject matter of Example 21 includes subject matter where the adjusting of the phase of the target phase signal comprises adjusting a rising edge of the target reference signal to be between a rising edge of the first reference signal and a rising edge of the second reference signal based on the calibration code.

In Example 23, the subject matter of Examples 21-22 includes selecting the first reference signal and the second reference signal from a subset of the plurality of phase signals, the subset comprising previously calibrated phase signals.

Example 24 is at least one machine-readable medium including instructions that, when executed by processing circuitry, cause the processing circuitry to perform operations to implement of any of Examples 1-23.

Example 25 is an apparatus comprising means to implement of any of Examples 1-23.

Example 26 is a system to implement of any of Examples 1-23.

Example 27 is a method to implement of any of Examples 1-23.

The above description is intended to be illustrative and not restrictive. For example, the above-described examples (or one or more aspects thereof) may be used in combination with others. Other embodiments may be used, such as by one of ordinary skill in the art upon reviewing the above description. The abstract is to allow the reader to ascertain the nature of the technical disclosure quickly. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. An apparatus comprising:
a first flip-flop circuit including a first input terminal and a second input terminal;
a second flip-flop circuit including a first input terminal and a second input terminal, the second input terminal of the first flip-flop circuit coupled to the first input terminal of the second flip-flop circuit;
a first phase interpolator (PI) circuit including an output terminal coupled to the first input terminal of the first flip-flop circuit; and
a second PI circuit including an output terminal coupled to the second input terminal of the second flip-flop circuit.

2. The apparatus of claim 1, further comprising:
a third PI circuit including an output terminal coupled to the second input terminal of the first flip-flop circuit and the first input terminal of the second flip-flop circuit.

3. The apparatus of claim 2, further comprising:
a comparator circuit including a first input terminal coupled to an output terminal of the first flip-flop circuit and a second input terminal coupled to an output terminal of the second flip-flop circuit.

4. The apparatus of claim 3, further comprising:
a calibration circuit including an input terminal coupled to an output terminal of the comparator circuit.

5. The apparatus of claim 4, wherein a first output terminal of the calibration circuit is coupled to the first PI circuit.

6. The apparatus of claim 5, wherein a second output terminal of the calibration circuit is coupled to the second PI circuit and wherein a third output terminal of the calibration circuit is coupled to the third PI circuit.

7. The apparatus of claim 6, further comprising one or more interconnects coupled to the first flip-flop circuit, the second flip-flop circuit, the first PI circuit, the second PI circuit, the third PI circuit, the comparator circuit, and the calibration circuit.

8. The apparatus of claim 7, further comprising a processor, and wherein the processor includes one or more of the first phase detector circuit, the second phase detector circuit, the first PI circuit, the second PI circuit, the third PI circuit, the comparator circuit, and the calibration circuit.

9. An apparatus comprising:
a first phase detector circuit configured to generate a first reference voltage signal based on a first phase difference between a target phase signal and a first reference signal;
a second phase detector circuit configured to generate a second reference voltage signal based on a second phase difference between the target phase signal and a second reference signal;
a comparator circuit configured to generate a comparison voltage output based on the first reference voltage signal and the second reference voltage signal; and
a calibration circuit configured to generate a plurality of control signals based on the comparison voltage output, at least one of the plurality of control signals comprising a calibration code causing adjustment of a phase associated with the target phase signal.

10. The apparatus of claim 9, further comprising:
a first phase interpolator (PI) circuit coupled to the first phase detector circuit, the first PI circuit to select the first reference signal from a plurality of phase signals based on a first control signal of the plurality of control signals.

11. The apparatus of claim 10, further comprising:
a second PI circuit coupled to the second phase detector circuit, the second PI circuit to select the second reference signal from the plurality of phase signals based on a second control signal of the plurality of control signals.

12. The apparatus of claim 11, further comprising:
a third PI circuit coupled to the first phase detector circuit and the second phase detector circuit, the third PI circuit to select the target reference signal from the plurality of phase signals based on the first control signal and the second control signal.

13. The apparatus of claim 12, wherein to perform the adjustment of the phase, the third PI circuit is to:
adjust a rising edge of the target reference signal based on the calibration code, the adjustment causing the rising edge of the target reference signal to be between a rising edge of the first reference signal and a rising edge of the second reference signal.

14. The apparatus of claim 12, wherein the first PI circuit is to select the first reference signal from a subset of the plurality of phase signals, the subset comprising previously calibrated phase signals.

15. The apparatus of claim 14, wherein the second PI circuit is to select the second reference signal from the subset of the plurality of phase signals.

16. A method comprising:
generating a first reference voltage signal based on a first phase difference between a target phase signal and a first reference signal;
generating a second reference voltage signal based on a second phase difference between the target phase signal and a second reference signal;
generating a comparison voltage output based on the first reference voltage signal and the second reference voltage signal;
generating a plurality of control signals based on the comparison voltage output; and
adjusting a phase of the target phase signal using a calibration code associated with at least one of the plurality of control signals.

17. The method of claim 16, further comprising:
selecting the first reference signal from a plurality of phase signals based on a first control signal of the plurality of control signals; and
selecting the second reference signal from the plurality of phase signals based on a second control signal of the plurality of control signals.

18. The method of claim 17, further comprising:
selecting the target reference signal from the plurality of phase signals based on the first control signal and the second control signal.

19. The method of claim 18, wherein the adjusting of the phase of the target phase signal comprises:
adjusting a rising edge of the target reference signal to be between a rising edge of the first reference signal and a rising edge of the second reference signal based on the calibration code.

20. The method of claim 18, further comprising:
selecting the first reference signal and the second reference signal from a subset of the plurality of phase signals, the subset comprising previously calibrated phase signals.
